(19) United States
(12) Patent Application Publication
(10) Pub. No.: US 2025/0132281 A1
(43) Pub. Date: Apr. 24, 2025

(54) SEMICONDUCTOR DEVICE

(71) Applicant: DENSO CORPORATION, Kariya-city (JP)

(72) Inventor: Nobuyuki KATO, Kariya-city (JP)

(21) Appl. No.: 19/000,827

(22) Filed: Dec. 24, 2024

Related U.S. Application Data
(63) Continuation of application No. PCT/JP2023/022273, filed on Jun. 15, 2023.

(30) Foreign Application Priority Data
Jul. 1, 2022 (JP) 2022-107162

(51) Int. Cl. H01L 23/00; H01L 23/495; H10D 84/00

(52) U.S. Cl. CPC H01L 24/29; H01L 24/05; H01L 24/32; H10D 84/161; H01L 23/495; H01L 24/33; H01L 2224/04026; H01L 2224/05124; H01L 2224/05155; H01L 2224/05557; H01L 2224/26122; H01L 2224/29076; H01L 2224/2908; H01L 2224/29111; H01L 2224/29147; H01L 2224/29155; H01L 2224/32058; H01L 2224/32503; H01L 2224/33181

(57) ABSTRACT

In a semiconductor device, a semiconductor element includes a semiconductor substrate and an upper electrode on a first surface of the semiconductor substrate. The semiconductor substrate has an IGBT region and a diode region. An upper conductor is disposed to face the upper electrode. An upper solder is interposed between the upper electrode and the upper conductor. An alloy layer is interposed between the upper electrode and the upper solder. The upper electrode includes an Al electrode disposed on the first surface and an Ni electrode disposed on the Al electrode. The upper solder contains Cu and Sn. The alloy layer contains Ni, Cu, and Sn. At least in a region overlapping with the diode region in a plan view along a thickness direction of the semiconductor substrate, a grain size of the upper solder is smaller on the semiconductor element side than on the upper conductor side.

### CROSS REFERENCE TO RELATED APPLICATIONS

The present application is a continuation application of International Patent Application No. PCT/JP2023/022273 filed on Jun. 15, 2023, which designated the U.S. and claims the benefit of priority from Japanese Patent Application No. 2022-107162 filed on Jul. 1, 2022. The entire disclosures of all of the above applications are incorporated herein by reference.

### TECHNICAL FIELD

The present disclosure relates to a semiconductor device.

### BACKGROUND

JP 2021-136311 A discloses a semiconductor device having an IGBT region and a diode region on a common semiconductor substrate. The disclosure of JP 2021-136311 A is incorporated herein by reference as an explanation of technical elements in the present disclosure.

### SUMMARY

The present disclosure provides a semiconductor device. According to an aspect, the semiconductor device includes: a semiconductor element including a semiconductor substrate having an IGBT region and a diode region and an upper electrode disposed on a first surface of the semiconductor substrate; an upper conductor disposed to face the upper electrode; an upper solder interposed between the upper electrode and the upper conductor and joining the upper electrode and the upper conductor; and an alloy layer interposed between the upper electrode and the upper solder.

### BRIEF DESCRIPTION OF DRAWINGS

Features and advantages of the present disclosure will become more apparent from the following detailed description made with reference to the accompanying drawings, in which:

FIG. 1 is a schematic diagram illustrating a configuration of a vehicle drive system to which a semiconductor device according to a first embodiment is applied;

FIG. 2 is a plan view of a semiconductor device according to the first embodiment;

FIG. 3 is a cross-sectional view taken along a line III-III in FIG. 2;

FIG. 4 is a cross-sectional view taken along a line IV-IV in FIG. 2;

FIG. 5 is a plan view of a semiconductor element of the semiconductor device;

FIG. 6 is a cross-sectional view taken along a line VI-VI in FIG. 5;

FIG. 7 is an enlarged cross-sectional view of a part around an emitter electrode of the semiconductor element;

FIG. 8 is an enlarged cross-sectional view of a part around an emitter electrode of a reference example;

FIG. 9 is a reference diagram illustrating the mechanism of electromigration (EM) progression;

FIG. 10 is a plan view of a semiconductor element of a semiconductor device according to a second embodiment;

FIG. 11 is a diagram illustrating a solder corresponding to an area XI in FIG. 10;

FIG. 12 is a cross-sectional view illustrating a method for manufacturing a semiconductor device according to a third embodiment;

FIG. 13 is an enlarged cross-sectional view of a part around an emitter electrode of a semiconductor device according to a fourth embodiment;

FIG. 14 is a cross-sectional view of a modification;

FIG. 15 is a cross-sectional view illustrating a method for manufacturing a semiconductor device according to a fifth embodiment; and

FIG. 16 is a cross-sectional view of a modification.

### DETAILED DESCRIPTION

In a semiconductor device adopting a reverse conductive integrated gate bipolar transistor (RC-IGBT) in which an IGBT and a freewheeling diode are integrated, the size of the semiconductor device can be reduced. However, since the area of a diode region is reduced by making the semiconductor device into a single chip, the current density is likely to increase in the diode region, which poses an issue of electromigration (EM). From the viewpoint mentioned above or from other viewpoints not mentioned, further improvement is required for semiconductor devices.

The present disclosure provides a semiconductor device capable of improving an EM lifetime.

According to an aspect of the present disclosure, a semiconductor device includes: a semiconductor element including a semiconductor substrate having an IGBT region and a diode region and an upper electrode disposed on a first surface of the semiconductor substrate; an upper conductor disposed to face the upper electrode; an upper solder interposed between the upper electrode and the upper conductor and joining the upper electrode and the upper conductor; and an alloy layer interposed between the upper electrode and the upper solder. The upper electrode includes an aluminum (Al) electrode disposed on the first surface and a nickel (Ni) electrode disposed on the Al electrode. The upper solder contains copper (Cu) and tin (Sn). The alloy layer contains Ni, Cu, and Sn. At least in a region overlapping with the diode region in a plan view along a thickness direction of the semiconductor substrate, a grain size of the upper solder is smaller on a side adjacent to the semiconductor element than on a side adjacent to the upper conductor.

According to the semiconductor device described above, in the region overlapping with the diode region where the current density is high, the grain size of the upper solder is small on the side adjacent to the semiconductor element. Therefore, it is possible to delay disappearance of the alloy layer and the Ni electrode due to the EM. As a result, the semiconductor device capable of improving the EM lifetime can be provided.

Hereinafter, embodiments of the present disclosure will be described with reference to the drawings. The same or corresponding elements are denoted by the same reference numerals throughout the embodiments, and descriptions thereof will not be repeated. When only part of the configuration is described in each embodiment, the configuration of the other preceding embodiments can be applied to other parts of the configuration. Further, not only the combinations of the configurations explicitly shown in the description of the respective embodiments, but also the configurations of the multiple embodiments can be partially combined even when they are not explicitly shown as long as there is no difficulty in the combination in particular.

A semiconductor device according to an embodiment is applied to a power conversion device of a movable object adopting, for example, a rotating electrical machine as a drive source. The movable object is, for example, an electrically driven vehicle such as a battery electric vehicle (BEV), a hybrid electric vehicle (HEV), or a plug-in hybrid electric vehicle (PHEV), a flying object, a ship, a construction machine, or an agricultural machine. The flying object may be, for example, an electric vertical takeoff and landing aircraft or a drone. Hereinafter, an example applied to a vehicle will be described.

### First Embodiment

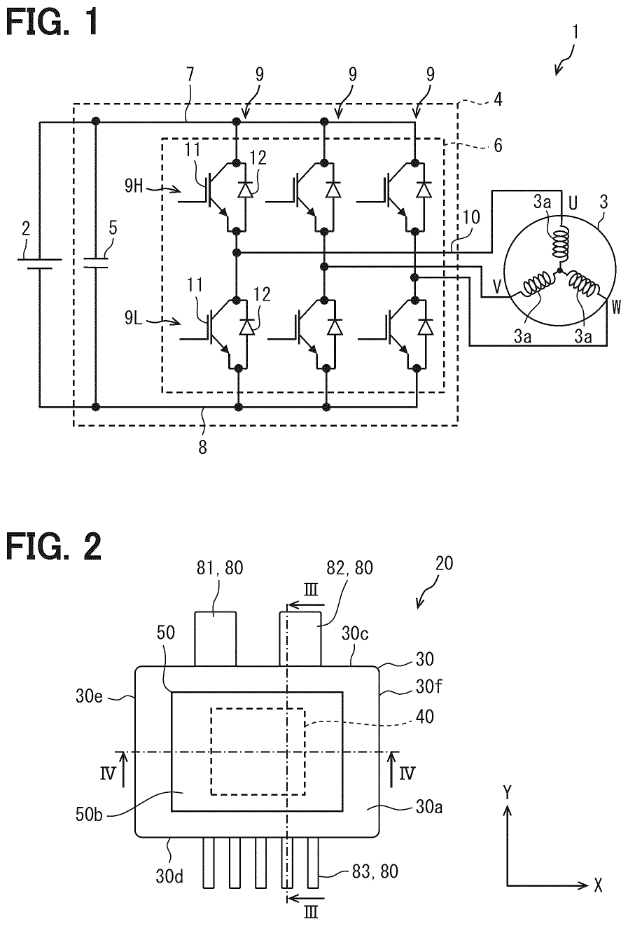

First, a schematic configuration of a vehicle drive system will be described with reference to FIG. 1.

### <Vehicle Drive System>

As shown in FIG. 1, a vehicle drive system 1 is provided with a direct current (DC) power supply 2, a motor generator 3, and a power conversion device 4.

The DC power supply 2 is a direct-current voltage source including a chargeable/dischargeable secondary battery. Examples of the secondary battery includes a lithium ion battery and a nickel hydride battery. The motor generator 3 is a three-phase alternating current (AC) type rotary electric machine. The motor generator 3 functions as a vehicle driving power source, that is, an electric motor. The motor generator 3 also functions as a generator during regeneration. The power conversion device 4 performs electric power conversion between the DC power supply 2 and the motor generator 3.

### <Power Conversion Device>

Next, a circuit configuration of the power conversion device 4 will be described with reference to FIG. 1. The power conversion device 4 includes a power conversion circuit. As shown in FIG. 1, the power conversion device 4 includes a smoothing capacitor 5 and an inverter 6, which is a power conversion circuit.

The smoothing capacitor 5 mainly smoothes the DC voltage supplied from the DC power supply 2. The smoothing capacitor 5 is connected between a P line 7, which is a power line on a high potential side, and an N line 8, which is a power line on a low potential side. The P line 7 is connected to a positive electrode of the DC power supply 2, and the N line 8 is connected to a negative electrode of the DC power supply 2. The positive electrode of the smoothing capacitor 5 is connected to the P line 7 at a position between the DC power supply 2 and the inverter 6. Similarly, the negative electrode of the smoothing capacitor 5 is connected to the N line 8 at a position between the DC power supply 2 and the inverter 6. The smoothing capacitor 5 is connected to the DC supply 2 in parallel.

The inverter 6 is a DC-AC conversion circuit. The inverter 6 converts the DC voltage into a three-phase AC voltage according to the switching control by a control circuit (not shown) and outputs the three-phase AC voltage to the motor generator 3. Thereby, the motor generator 3 is driven to generate a predetermined torque. At the time of regenerative braking of the vehicle, the inverter 6 converts the three-phase AC voltage generated by the motor generator 3 by receiving the rotational force from wheels into a DC voltage according to the switching control by the control circuit, and outputs the DC voltage to the P line 7. In this way, the inverter 6 performs bidirectional power conversion between the DC power supply 2 and the motor generator 3.

The inverter 6 includes upper-lower arm circuits 9 for three phases. The upper-lower arm circuit 9 is also referred to as a leg. The upper-lower arm circuit 9 includes an upper arm 9H and a lower arm 9L. The upper arm 9H and the lower arm 9L are connected in series between the P line 7 and the N line 8, with the upper arm 9H being on the P line 7 side. A connection point between the upper arm 9H and the lower arm 9L is connected to a winding 3a of a corresponding phase in the motor generator 3 via an output line 10. The inverter 6 has six arms. At least a part of each of the P line 7, the N line 8 and the output line 10 is made of a conductive member such as a bus bar.

Each arm includes, as elements, an IGBT 11 which is a switching element, and a freewheeling diode 12. IGBT is an abbreviation for insulated gate bipolar transistor. In the present embodiment, an n-channel IGBT 11 is used. The diode 12 is connected in anti-parallel to the corresponding IGBT 11. In the upper arm 9H, the collector of the IGBT 11 is connected to the P line 7. In the lower arm 9L, the emitter of the IGBT 11 is connected to the N line 8. The emitter of the IGBT 11 in the upper arm 9H and the collector of the IGBT 11 in the lower arm 9L are connected to each other. The anode of the diode 12 is connected to the emitter of the corresponding IGBT 11, and the cathode of the diode 12 is connected to the collector of the corresponding IGBT 11.

The power conversion device 4 may further include a converter as a power conversion circuit. The converter is a DC-DC converter circuit for converting the DC voltage to a DC voltage with different value. The converter is disposed between the DC power supply 2 and the smoothing capacitor 5. The converter is configured to include, for example, a reactor and the upper-lower arm circuit 9 as described above. Such a configuration can boost and suppress the voltage. The power conversion device 4 may further include a filter capacitor for removing power supply noise from the DC power supply 2. The filter capacitor is provided between the DC power supply 2 and the converter.

The power conversion device 4 may include a drive circuit for switching elements constituting the inverter 6 and the like. The drive circuit supplies a drive voltage to the gate of the IGBT 11 of the corresponding arm based on a drive command of a control circuit. The drive circuit drives the corresponding IGBT, that is, turns on and off the corresponding IGBT 11 by applying the drive voltage. The drive circuit may be referred to as a “driver”.

The power conversion device 4 may include a control circuit for the switching element. The control circuit generates a drive command for operating the IGBT 11 and outputs the drive command to the drive circuit. The control circuit generates the drive command based on a torque request input from a higher-level ECU (not shown) or signals detected by various sensors. Examples of the various sensors include a current sensor, a rotation angle sensor, and a voltage sensor. The current sensor detects the phase current flowing through the winding 3a of each phase. The rotation angle sensor detects a rotation angle of a rotor of the motor generator 3. The voltage sensor detects the voltage across the smoothing capacitor 5. The control circuit outputs, for example, a PWM signal as the drive command. The control circuit is configured to include, for example, a processor and a memory. ECU is an abbreviation for electronic control unit. PWM is an abbreviation for pulse width modulation.

### <Semiconductor Device>

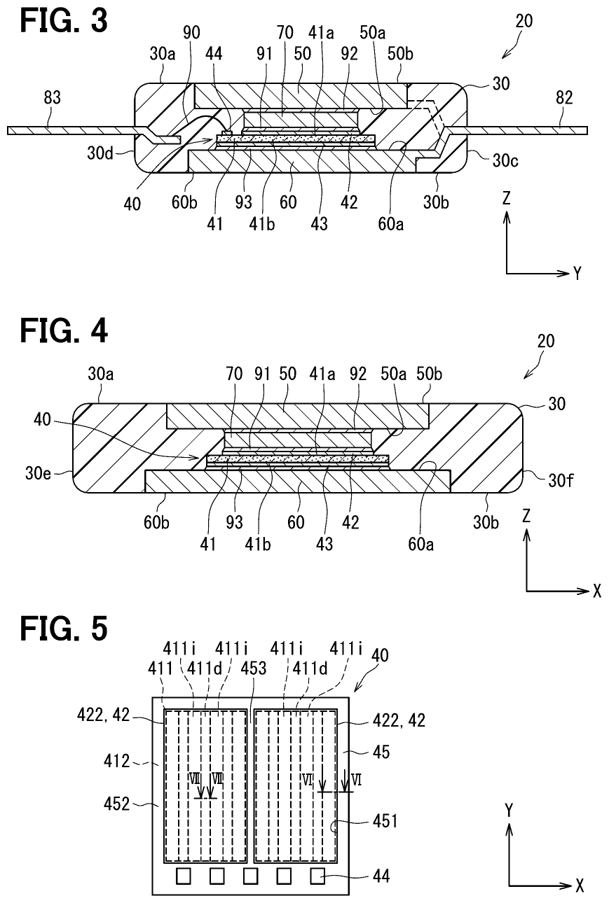

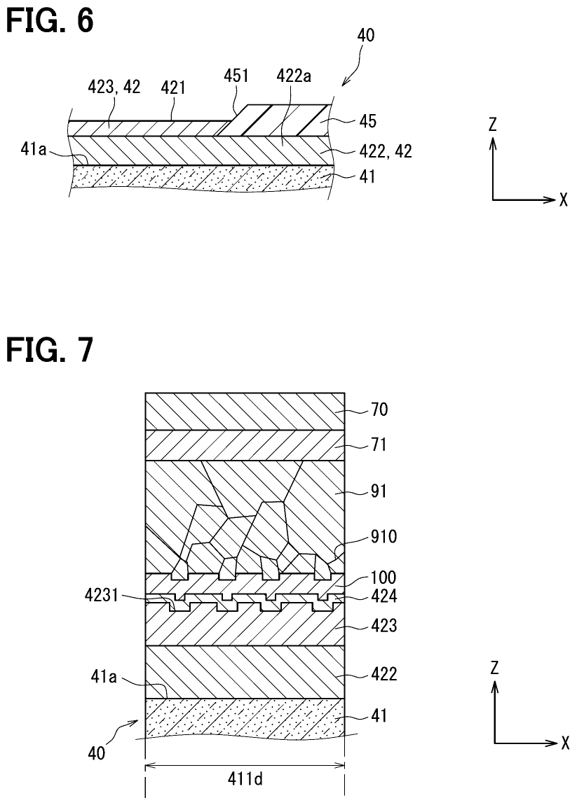

Next, a schematic configuration of the semiconductor device will be described with reference to FIGS. 2 to 6. FIG. 2 is a plan view illustrating the semiconductor device. FIG. 2 is a top plan view of the semiconductor device. FIG. 3 is a cross-sectional view taken along a line III-III in FIG. 2. FIG. 4 is a cross-sectional view taken along a line IV-IV in FIG. 2. FIG. 5 is a plan view illustrating a semiconductor element. FIG. 6 is a cross-sectional view taken along a line VI-VI in FIG. 5.

Hereinafter, a thickness direction of a semiconductor element (semiconductor substrate) is referred to as a Z direction. A direction perpendicular to the Z direction is referred to as an X direction. A direction perpendicular to both the Z direction and the X direction is referred to as a Y direction. Unless otherwise specified, a shape in a plan view when viewed along the Z direction, that is, a shape along an XY plane including the X direction and Y direction is referred to as a planar shape. Furthermore, the plan view when viewed along the Z direction may simply be referred to as the plan view.

As shown in FIGS. 2 to 6, a semiconductor device 20 includes a sealing body 30, a semiconductor element 40, wiring members 50 and 60, a conductive spacer 70, and an external connection terminal 80. The semiconductor device 20 further includes a bonding wire 90 and solder 91 to 93. The semiconductor device 20 constitutes one of the arms described above. That is, the two semiconductor devices 20 constitute the upper-lower arm circuit 9 for one phase.

The sealing body 30 seals part of other elements constituting the semiconductor device 20. The rest of the other elements are exposed to the outside of the sealing body 30. The sealing body 30 includes, for example, a resin. An example of the resin is an epoxy resin. The sealing body 30 is molded by, for example, a transfer molding method using the resin as a material. Such a sealing body 30 may be referred to as a sealing resin body, a molded resin, a resin molded body, or the like. The sealing body 30 may be made using, for example, gel. The gel is filled (placed) in a facing region between the pair of wiring members 50 and 60, for example.

As shown in FIGS. 2 to 4, the sealing body 30 has a substantially rectangular shape in the plan view. The sealing body 30 has, as surfaces forming an outer contour, a first surface 30a and a second surface 30b as a back surface opposite to the first surface 30a in the Z direction. The first surface 30a and the second surface 30b are, for example, substantially flat surfaces. The sealing body 30 further has side surfaces 30c, 30d, 30e and 30f each connecting between the first surface 30a and the second surface 30b. The side surface 30c is a surface from which main terminals 81 and 82 of the external connection terminal 80 protrude. The side surface 30d is a surface opposite to the side surface 30c in the Y direction. The side surface 30d is the surface from which the signal terminal 83 protrude. The side surfaces 30e and 30f are surfaces from which the external connection terminal 80 does not protrude. The side surface 30e is the surface opposite to the side surface 30f in the X direction.

The semiconductor element 40 includes a semiconductor substrate 41, an emitter electrode 42, a collector electrode 43, and a pad 44. The semiconductor element 40 is also referred to as a semiconductor chip. The semiconductor substrate 41 is made of a material such as silicon (Si) or a wide bandgap semiconductor having a wider band gap than silicon, and has a vertical element formed thereon. Examples of the wide bandgap semiconductor include silicon carbide (SiC), gallium nitride (GaN), gallium oxide (Ga₂O₃) and diamond.

The vertical element is configured to cause a main current to flow in the thickness direction of the semiconductor substrate 41 (semiconductor element 40), that is, in the Z direction. In the present embodiment, the vertical element includes the IGBT 11 and the diode 12, which form one arm. The vertical element is an IGBT with which the diode 12 connected in anti-parallel, that is, a RC-IGBT. RC is an abbreviation for reverse conducting. The vertical element is a heat generation element that generates heat when being applied with electricity. The semiconductor substrate 41 is provided with a gate electrode (not shown). The gate electrode has, for example, a trench structure.

As shown in FIG. 5, the semiconductor substrate 41 has a generally rectangular shape in the plan view. The semiconductor substrate 41 has an active region 411 and a peripheral region 412. The active region 411 is a region where the vertical elements are formed. The active region 411 may be also referred to as a main region, a main cell region, a cell region, an element region, an element forming region, or the like. The peripheral region 412 is formed with a voltage withstand structure (not shown), such as a guard ring.

The active region 411 is aligned with the pad 44 in the Y direction. The active region 411 has, for example, a substantially rectangular shape in the plan view. The active region 411 includes an IGBT region 411i, which is a region where an IGBT is formed, and a diode region 411d, which is a region where a diode is formed, of the RC-IGBT. The IGBT regions 411i and the diode regions 411d are arranged alternately in the X direction. The active region 411 is provided with multiple cells (unit structural parts). The multiple cells are connected in parallel to each other to form the RC-IGBT. As an example, the IGBT regions 411i and the diode regions 411d are arranged alternately at a predetermined pitch. Both ends in the arrangement direction are provided by the IGBT regions 411i. In the plan view, the area of the IGBT region 411i is larger than that of the diode region 411d.

The semiconductor substrate 41 has a first surface 41a and a second surface 41b, as plate surfaces on which main electrodes are provided. The first surface 41a is the surface of the semiconductor substrate 41 on the first surface 30a side of the sealing body 30. The second surface 41b is the surface opposite to the first surface 41a in the thickness direction. An emitter electrode 42, which is one of the main electrodes, is disposed on the first surface 41a of the semiconductor substrate 41. A collector electrode 43, which is another one of the main electrodes, is disposed on the second surface 41b of the semiconductor substrate 41.

When the IGBT 11 is turned on, current (main current) flows between the main electrodes, that is, between the emitter electrode 42 and the collector electrode 43. The emitter electrode 42 also serves as the anode electrode of the diode 12. The collector electrode 43 also serves as the cathode electrode of the diode 12. The collector electrode 43 is formed over almost the entire second surface 41b of the semiconductor substrate 41. The emitter electrode 42 is formed in a part of the first surface 41a of the semiconductor substrate 41. The emitter electrode 42 corresponds to an upper electrode, and the collector electrode 43 corresponds to a lower electrode.

The pad 44 is an electrode for a signal. The pad 44 is formed in a region on the first surface 41a of the semiconductor substrate 41, the region being different from the region in which the emitter electrode 42 is formed. The pad 44 is formed at an end on a side opposite to the region where the emitter electrode 42 is formed in the Y direction. The pad 44 is disposed side by side with the emitter electrode 42 in the Y direction. The number of pad(s) 44 is not particularly limited. The pad 44 includes at least a pad for a gate electrode.

As an example, the semiconductor element 40 has five pads 44, as shown in FIG. 5. Specifically, the five pads 44 include a pad for the gate electrode, a pad for detecting an emitter potential, a pad for detecting a cathode potential of a temperature sensing diode (not shown) provided in the semiconductor element 40, a pad for detecting an anode potential, and a pad for sensing a current. The five pads 44 are aligned in the X direction.

As shown in FIGS. 5 and 6, the semiconductor element 40 includes a protective film 45 disposed on the first surface 41a of the semiconductor substrate 41. The protective film 45 is an insulating film disposed on the first surface 41a of the semiconductor substrate 41 so as to cover the peripheral portion of the emitter electrode 42, specifically, an aluminum (Al) electrode 422, which will be described later. As a material of the protective film 45, for example, polyimide, silicon nitride, or the like can be adopted.

The protective film 45 includes an opening portion 451, an outer peripheral portion 452 and a partition portion 453. The opening portion 451 defines a bonding area between the emitter electrode 42 and the solder 91. The opening portion 451 forms a through-hole that penetrates the protective film 45 in the Z direction. The opening portion 451 is disposed so as to overlap with the emitter electrode 42 in the plan view. The opening portion 451 generally coincides with the active region 411 in the plan view. Similarly, the protective film 45 further has an opening portion (not shown) that defines a bonding area of the pad 44.

The outer peripheral portion 452 is disposed at the outer peripheral area of the semiconductor element 40. The outer peripheral portion 452 is disposed so as to substantially coincide with the outer peripheral region 412 in the plan view. The partition portion 453 divides the Ni electrode 423 into multiple sections. As an example, the partition portion 453 of the present embodiment is disposed so as to divide the Ni electrode 423 into generally two equal parts in the X direction. The partition portion 453 divides the opening portion 451 into two sections. The partition portion 453 passes through the center of the semiconductor element 40 and extends in the Y direction. One end of the partition portion 453 is connected to the outer peripheral portion 452 on a side adjacent to the pad 44, and the other end is connected to the outer peripheral portion 452 on the side opposite to the pad 44 in the Y direction.

The emitter electrode 42 has an exposed portion 421 that is exposed from the opening portion 451 of the protective film 45 and provides a bonding region. The exposed portion 421 forms a bonding portion with the solder 91. In the plan view, the outer contour of the exposed portion 421 coincides with the outer contour of the opening portion 451. The exposed portion 421 is disposed above the active region 411 of the semiconductor substrate 41. The emitter electrode 42 has a multi-layer structure. The emitter electrode 42 includes the Al electrode 422 and a nickel (Ni) electrode 423. The pad 44 has a similar structure to the emitter electrode 42.

The Al electrode 422 is a metal layer formed adjacent to the semiconductor substrate 41 in the emitter electrode 42 of the multi-layer structure. The Al electrode 422 is formed using a material containing aluminum (Al) as a main component. In the present embodiment, an example of the material of the Al electrode 422 is an Al alloy such as AlSi or AlSiCu. The Al electrode 422 may be referred to as a base electrode, a wiring electrode, a base layer, a first metal layer, or the like. The Al electrode 422 is connected to the first surface 41a of the semiconductor substrate 41.

The Al electrode 422 is disposed to enclose the active region 411 in the plan view and is extended onto the outer peripheral region 412. The Al electrode 422 is connected to the emitter and the anode of the vertical element. The Al electrode 422 has a peripheral portion 422a that surrounds the exposed portion 421 in the plan view. The peripheral portion 422a is a portion of the Al electrode 422 that overlaps with the protective film 45. The protective film 45 is disposed on the first surface 41a of the semiconductor substrate 41 so as to cover the peripheral portion 422a of the Al electrode 422.

The Ni electrode 423 is stacked on the Al electrode 422 in order to improve the bonding strength with the solder 91 and to improve the wettability with the solder 91. The Ni electrode 423 is formed using a material containing nickel (Ni) as a main component. In the present embodiment, as an example, the Ni electrode 423 is a NiP film formed by electroless plating. The Ni electrode 423 is a Ni plating film containing phosphorous (P). The Ni electrode 423 may be referred to as an upper electrode, a connection electrode, an upper layer, a second metal layer, a plating layer, a sound layer, or the like.

Ni is harder than the Al alloy that forms the Al electrode 422. In addition, a gold (Au) electrode may be further formed on the Ni electrode 423 during the manufacturing process. For example, Au suppresses oxidation of Ni and improves the wettability with the solder 91. Since Au diffuses into the solder during soldering, Au is present in the state before bonding and is not present in a bonded state.

The Ni electrode 423 is stacked on the Al electrode 422 and is exposed from the opening portion 451. In the present embodiment, as an example, the Ni electrode 423 is disposed on the Al electrode 422 within the opening portion 451. The outer peripheral edge of the Ni electrode 423 is in contact with the wall surface of the protective film 45 that defines the opening portion 451.

The wiring member 50 is electrically connected to the emitter electrode 42 and provides a wiring function. Similarly, the wiring member 60 is electrically connected to the collector electrode 43 and provides a wiring function. The wiring members 50 and 60 are disposed so as to interpose the semiconductor element 40 therebetween in the Z direction. The wiring members 50 and 60 are disposed so as to face each other at least at a part in the Z direction. The wiring members 50 and 60 enclose the semiconductor element 40 in the plan view. The wiring member 60 corresponds to a lower conductor.

The wiring members 50 and 60 provide a heat dissipation function for dissipating heat generated by the semiconductor element 40. The wiring members 50 and 60 are also referred to as heat dissipation plates, heat sinks, or the like. The wiring members 50 and 60 of the present embodiment are metal plates made of a metal with favorable electrical conductivity, such as Cu or a Cu alloy. The metal plate is provided, for example, as a part of a lead frame. Instead of the metal plate, a substrate having metal bodies disposed on both sides of an insulating base material may be used. The wiring members 50 and 60 may have a plating film of Ni, Au, or the like on the surface thereof.

The wiring member 50 has a facing surface 50a, which is the surface on a side adjacent to the semiconductor element 40, and a back surface 50b, which is the surface opposite to the facing surface 50a. Similarly, the wiring member 60 has a facing surface 60a and a back surface 60b. The wiring members 50 and 60 have, for example, a substantially rectangular shape in the plan view. The back surfaces 50b and 60b of the wiring members 50 and 60 are exposed from the sealing body 30, respectively. The back surfaces 50b and 60b are also referred to as heat dissipation surfaces, exposed surfaces, or the like. The back surface 50b of the wiring member 50 is substantially flush with the first surface 30a of the sealing body 30. The back surface 60b of the wiring member 60 is substantially flush with the second surface 30b of the sealing body 30.

The conductive spacer 70 is interposed between the semiconductor element 40 and the wiring member 50. The conductive spacer 70 provides a spacer function for ensuring a predetermined distance between the semiconductor element 40 and the wiring member 50. For example, the conductive spacer 70 secures a height for electrically connecting a signal terminal 83 to the corresponding pad 44 of the semiconductor element 40. The conductive spacer 70 is located on electrical conduction and thermal conduction paths between the emitter electrode 42 of the semiconductor element 40 and the wiring member 50, and provides a wiring function and a heat dissipation function. The conductive spacer 70 corresponds to an upper conductor.

The conductive spacer 70 contains a metal material, such as copper (Cu), that has favorable electrical and thermal conductivity. The conductive spacer 70 may have a plating film on a surface thereof. The conductive spacer 70 may be referred to as a terminal, a terminal block, a metal block, or the like. In the present embodiment, the conductive spacer 70 is a columnar body having a substantially rectangular shape in the plan view.

The external connection terminal 80 is a terminal for electrically connecting the semiconductor device 20 to an external device. The external connection terminal 80 is formed using a metal material, such as Cu, that has favorable conductivity. The external connection terminal 80 is, for example, a plate member. The external connection terminal 80 may be referred to as a “lead”. The external connection terminal 80 includes main terminals 81 and 82 and the signal terminal 83. The main terminals 81 and 82 are external connection terminals 80 electrically connected to the main electrodes of the semiconductor element 40.

The main terminal 81 is electrically connected to the emitter electrode 42. The main terminal 81 is also referred to as an emitter terminal. The main terminal 81 is connected to the emitter electrode 42 via the wiring member 50. The main terminal 81 is connected to one end of the wiring member 50 in the Y direction. The thickness of the main terminal 81 is thinner than that of the wiring member 50. For example, the main terminal 81 is connected to the wiring member 50 so as to be substantially flush with the facing surface 50a. The main terminal 81 may be connected to the wiring member 50 by being formed continuously and integrally therewith, or may be provided as a separate member and connected to the wiring member 50 by bonding.

In the present embodiment, the main terminal 81 is provided integrally with the wiring member 50 as a part of the lead frame. The main terminal 81 extends in the Y direction from the wiring member 50 and protrudes to the outside of the sealing body 30 from the side surface 30c. The main terminal 81 has a bent portion in a part covered by the sealing body 30, and protrudes from the vicinity of the center in the Z direction on the side surface 30c.

The main terminal 82 is electrically connected to the collector electrode 43. The main terminal 82 is also referred to as a collector terminal. The main terminal 82 is connected to the collector electrode 43 via the wiring member 60. The main terminal 82 is connected to one end of the wiring member 60 in the Y direction. The thickness of the main terminal 82 is thinner than that of the wiring member 60. The main terminal 82 is connected to the wiring member 60 so as to be substantially flush with the facing surface 60a, for example. The main terminal 82 may be connected to the wiring member 60 by being formed continuously and integrally therewith, or may be provided as a separate member and connected to the wiring member 60 by bonding.

In the present embodiment, the main terminal 82 is provided integrally with the wiring member 60 as a part of a lead frame separate from the main terminal 81. The main terminal 82 extends in the Y direction from the wiring member 60 and protrudes to the outside of the sealing body 30 from the same side surface 30c as the main terminal 81. Similar to the main terminal 81, the main terminal 82 has a bent portion in a part covered by the sealing body 30, and protrudes from the vicinity of the center in the Z direction on the side surface 30c. The two main terminals 81 and 82 are arranged side by side in the X direction so that the side surfaces thereof face each other in the X direction.

The signal terminal 83 is electrically connected to the corresponding pad 44 of the semiconductor element 40. The signal terminal 83 is electrically connected to the pad 44 via a bonding wire 90. The signal terminal 83 extends in the Y direction and protrudes to the outside of the sealing body 30 from the side surface 30d of the sealing body 30. In the present embodiment, the semiconductor device 20 includes five signal terminals 83 corresponding to the pads 44. The five signal terminals 83 are arranged side by side in the X direction. The signal terminals 83 are formed in a lead frame common to the wiring members 60 and the main terminal 82, for example. The multiple signal terminals 83 are electrically isolated from one another by cutting tie bars (not shown).

The solder 91 is interposed between the emitter electrode 42 of the semiconductor element 40 and the conductive spacer 70, and bonds the emitter electrode 42 and the conductive spacer 70 to each other. The solder 91 is also referred to as an on-element solder. The solder 91 corresponds to an upper solder. The solder 92 is interposed between the conductive spacer 70 and the wiring member 50, and bonds the conductive spacer 70 and the wiring member 50 to each other. The solder 92 is also referred to as an on-spacer solder. The solder 93 is interposed between the collector electrode 43 of the semiconductor element 40 and the wiring member 60, and bonds the collector electrode 43 and the wiring member 60 to each other. The solder 93 is also referred to as an under-element solder. The solder 93 corresponds to a lower solder.

The solders 91 to 93 may be made of a same material or may be made of different materials. The solder 91 contains Cu and tin (Sn). The solder 91 is, for example, a multi-element lead-free solder containing Cu, bismuth (Bi), antimony (Sb), or the like and the remainder being made of Sn.

As described above, in the semiconductor device 20, the semiconductor element 40 that constitutes one arm is sealed by the sealing body 30. The sealing body 30 integrally seals the semiconductor element 40, a portion of the wiring member 50, a portion of the wiring member 60, the conductive spacer 70, and a portion of each of the external connection terminals 80.

The semiconductor element 40 is disposed between the wiring members 50 and 60 in the Z direction. The semiconductor element 40 is interposed between the wiring members 50 and 60, which are arranged to face each other. Thereby, the heat of the semiconductor element 40 can be dissipated from both sides in the Z-direction. The semiconductor device 20 has a double-sided heat dissipation structure. The back surface 50b of the wiring member 50 is substantially flush with the first surface 30a of the sealing body 30. The back surface 60b of the wiring member 60 is substantially flush with the second surface 30b of the sealing body 30. Since the back surfaces 50b and 60b are the exposed surfaces, it is possible to enhance the heat dissipation.

### <Element Upper Structure and Solder Grain Size>

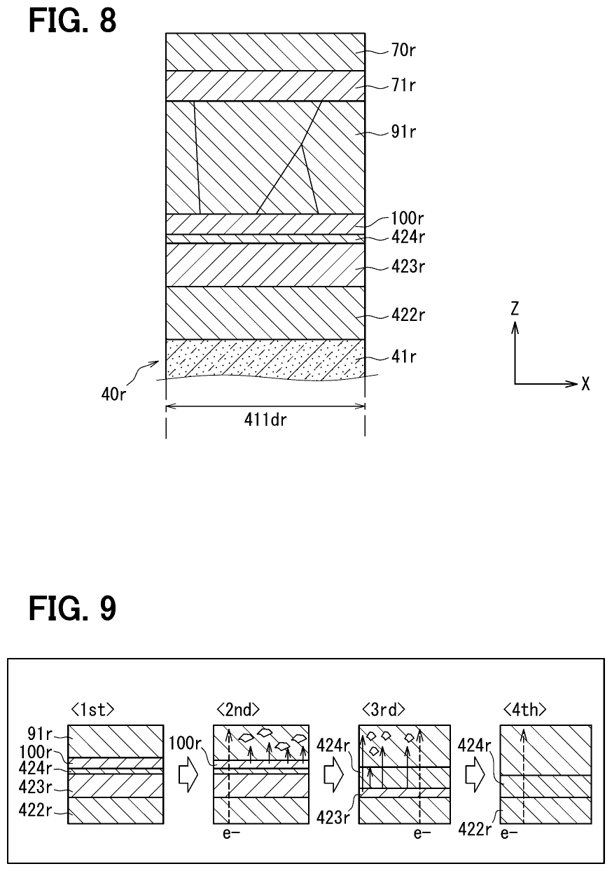

Next, an element upper structure and a solder grain size will be described with reference to FIG. 7 and FIG. 8. FIG. 7 is a cross-sectional view illustrating the element upper structure of the semiconductor device 20 according to the present embodiment. FIG. 7 is an enlarged cross-sectional view of the emitter electrode 42 and its periphery. FIG. 7 is a cross-sectional view taken along a line VII-VII in FIG. 5. FIG. 8 is a cross-sectional view of an element upper structure of a semiconductor device according to a reference example. In the reference example, “r” is added to the end of the reference sign of a related component of the semiconductor device 20, and the sign thus obtained is used as the reference sign of each component.

As shown in FIG. 7, the semiconductor device 20 includes an alloy layer 100 interposed between the Ni electrode 423 and the solder 91. The alloy layer 100 is also referred to as IMC. IMC is an abbreviation for intermetallic compound. The alloy layer 100 is formed during the bonding. The alloy layer 100 contains Ni, Cu, and Sn. The composition of the alloy layer 100 is, for example, (Ni—Cu)₃Sn₄.

The semiconductor device 20 further includes a P-rich layer 424. The P-rich layer 424 is formed on the surface of the Ni electrode 423. The P-rich layer 424 is formed by diffusing a part of Ni of the Ni electrode 423 toward the solder 91 during the bonding. The P-rich layer 424 is a layer in which the content of phosphorous (P) is higher than that in the Ni electrode 423 (NiP). The composition of the P-rich layer 424 is, for example, Ni₃P.

The Ni electrode 423 has an uneven portion 4231 having a continuous unevenness on the surface at least in a region overlapping with the diode region 411d. The uneven portion 4231 is provided by recesses and protrusions which are arranged repeatedly and continuously in the X direction, for example. The repeating direction of the uneven portion 4231 is not limited to the X direction. For example, it may be the Y direction, or the X and Y directions. The recesses and protrusions of the uneven portions 4231 may be arranged in a checkered pattern. The height of the uneven portion 4231 is, for example, about 1 μm. Since the Ni electrode 423 has the uneven portion 4231, the P-rich layer 424 and the alloy layer 100 disposed on the Ni electrode 423 also have the uneven shape.

The uneven portion 4231 is formed, for example, by patterning the surface of the Ni electrode 423. Alternatively, the uneven portion 4231 on the surface of the Ni electrode 423 may be provided by forming the Al electrode 422 located directly below the Ni electrode 423 with an uneven structure. The uneven portion 4231 on the surface of the Ni electrode 423 may be provided by forming an uneven structure on the first surface 41a of the semiconductor substrate 41 using an interlayer insulating film or the like.

The solder 91 starts to grow into grains from the unevenness originating from the Ni electrode 423 as a starting point, when the solder 91 solidifies. When the adjacent grains collide, grain boundaries 910 are formed. The crystal grains grow from the unevenness as the starting point, and are smaller on the semiconductor element 40 side. Therefore, at least in the region overlapping with the diode region 411d, the grain size of the solder 91 is smaller on the semiconductor element 40 side than on the conductive spacer 70 side. The part of the solder 91 adjacent to the semiconductor element 40 than the center in the Z direction is referred to as the semiconductor element 40 side or the part adjacent to the semiconductor element 40, and the part of the solder 91 adjacent to the conductive spacer 70 than the center is referred to as the conductive spacer 70 side or the part adjacent to the conductive spacer 70 side.

Although not shown, the grain size of the part of the solder 91 adjacent to the semiconductor element 40, at least in the region overlapping with the diode region 411d, is smaller than the grain size of the solder 93. The thickness of the solder 91 is, for example, about 100 μm. In the example shown in FIG. 7, the conductive spacer 70 has a plating film 71 on its surface. The plating film 71 is mainly made of Ni, similar to the Ni electrode 423. For convenience, an alloy layer between the plating film 71 and the solder 91 is omitted from the illustration. As shown in FIG. 7, the plating film 71 is not formed with the unevenness.

In the comparative example shown in FIG. 8, the surface of the Ni electrode 423r is not formed with the unevenness. In other words, the grain size of the solder 91r is not controlled. The other configurations of the comparative example are similar to those of the semiconductor device 20 of the present embodiment. In such a case, the grain size of the solder 911r is about 100 μm. The solder 911r has one or two crystal grains in the thickness direction (Z direction) of the solder 91. Therefore, over the entire region of the solder 91r, the grain sizes of both the part adjacent to the semiconductor element 40r and the part adjacent to the conductive spacer 70r are large. The grain size of the part of the solder 91r adjacent to the semiconductor element 40r and the grain size of the part of the solder 91r adjacent to the conductive spacer 70r are approximately the same.

### <EM>

Next, electromigration (EM) will be described with reference to FIG. 9. FIG. 9 is a reference diagram illustrating the mechanism of EM progression. Also in FIG. 9, the reference numerals of the elements are the same as those of the semiconductor device 20 with the letter r added to the end. In the example shown in the reference diagram, similar to the configuration shown in FIG. 8, the grain size of the solder 91r is not controlled. The other configurations are similar to those of the semiconductor device 20 of the present embodiment.

In FIG. 9, the 1st stage shows an initial stage before current is applied. An alloy layer 100r is interposed between a Ni electrode 423r and a solder 91r. In addition, a P-rich layer 424r is formed on the surface of the Ni electrode 423r.

The 2nd, 3rd and 4th stages in FIG. 9 show the application stages of a return current. A dashed arrow indicates the flow direction of electron (e−). That is, the return current flows from the conductive spacer (not shown) to the semiconductor element. The return current is the current that flows when the diode is operating.

As shown in the 2nd stage of FIG. 9, Cu and other elements of the alloy layer 100r above the diode region move (diffuse) toward the conductive spacer as the electrons move. Specifically, metals such as Cu are ionized and move toward the conductive spacer. As a result, the alloy layer 100r gradually becomes thinner and disappears as shown in the 3rd stage of FIG. 9.

When the alloy layer 100r disappears, as shown in the 3rd stage of FIG. 9, Ni of the Ni electrode 423r moves (diffuses) toward the conductive spacer with the movement of electrons. Thus, the Ni electrode 423r decreases, and the P-rich layer 424r increases. Then, as shown in the 4th stage of FIG. 9, the Ni electrode 423r disappears, and the P-rich layer 424r reaches the Al electrode 422r. That is, the P-rich layer 424r replaces the Ni electrode 423r.

After the P-rich layer 424r reaches the Al electrode 422r, the adhesion decreases over time, causing, for example, voids. Further, cracks along the interface are generated from the voids as the starting point.

As described above, in the configuration where the solder grain size is not controlled (see FIG. 8), the grain size of the solder 91 is large. There are few grain boundaries in the migration path of Cu. Therefore, Cu in the alloy layer 100r is likely to move along with the movement of electrons.

On the other hand, in the configuration of the present embodiment (see FIG. 7), the grain size of the solder 91 is smaller on the semiconductor element 40 side than on the conductive spacer 70 side, in the region directly above the diode region 411d where the current density is high. In other words, there are more grain boundaries 910 in the part of the solder 91 adjacent to the semiconductor element 40. Therefore, Cu in the alloy layer 100 does not easily move in association with the movement of electrons. In other words, the alloy layer 100 is unlikely to disappear. The time necessary for the alloy layer 100 to disappear increases. This delays the time necessary for the Ni electrode 423 to become the P-rich layer 424 and begin to decrease. The time necessary for the Ni electrode 423 to disappear becomes longer.

### <Summary of First Embodiment>

By adopting the RC-IGBT in which the IGBT 11 and the diode 12 are integrated into a single chip, for example, the size of the semiconductor device 20 can be reduced. However, the area of the diode region 411d is reduced by the integration into the single chip, and the current density is increased in the diode region 411d.

In the present embodiment, at least in the region overlapping with the diode region 411d, the grain size of the solder 91 is smaller on the semiconductor element 40 side than on the conductive spacer 70 side. There are many grain boundaries 910 in the part adjacent to the semiconductor element 40. The grain boundaries 910 hinder the movement of Cu. Therefore, Cu in the alloy layer 100 does not easily move in association with the movement of electrons. As such, the time necessary for the alloy layer 100 to disappear can be increased. In addition, the time necessary for the Ni electrode 423 to disappear can be increased. As a result, the EM lifetime can be improved. In particular, in the present embodiment, the area of the diode region 411d is smaller than the area of the IGBT region 411i, and the current density of the current path is maximum in the diode region 411d. However, since the grain size of the part of the solder 91 on the semiconductor element 40 side is made small, the EM lifetime can be improved.

The effect of the particle size of the solder 91 was confirmed through prototypes. It was confirmed that the reduction in the grain size of the part of the solder 91 adjacent to the semiconductor element 40 delayed the disappearance of the alloy layer 100, that is, delayed the progression of EM. In this time, the Ni electrode 423 was formed by an electroless NiP plating. The composition of the alloy layer 100 was (Ni—Cu)₃Sn₄.

It is sufficient that, at least in the region overlapping with the diode region 411d, the grain size of the solder 91 is smaller on the semiconductor element 40 side than on the conductive spacer 70 side. For example, the grain size of the solder 91 may be smaller on the semiconductor element 40 side than on the conductive spacer 70 side, only in the region overlapping with the diode region 411d. The grain size of the solder 91 may be smaller on the semiconductor element 40 side than on the conductive spacer 70 side in the diode region 411d and the IGBT region 411i.

In the present embodiment, the grain size of the part of the solder 91 adjacent to the semiconductor element 40 at least in the region overlapping with the diode region 411d is smaller than the grain size of the solder 93. The solder particle size of the solder 93 is not controlled and is large. By controlling the grain size, the grain size of the part of the solder 91 adjacent to the semiconductor element 40 is smaller than that of the solder 93 at least in the region overlapping with the diode region 411d. Therefore, at least in the region overlapping with the diode region 411d, there are many grain boundaries 910 in the part of the solder 91 adjacent to the semiconductor element 40. The grain boundaries 910 hinder the movement of Cu. Therefore, Cu in the alloy layer 100 does not easily move in association with the movement of electrons. As such, the time necessary for the alloy layer 100 to disappear can be increased. In addition, the time necessary for the Ni electrode 423 to disappear can be increased.

In the present embodiment, the Ni electrode 423 has the uneven portion 4231, in which unevenness is continuously formed, on the surface at least in the region overlapping with the diode region 411d. In this manner, by providing the uneven portion 4231 on the Ni electrode 423, the grain size becomes smaller on the semiconductor element 40 side. The EM lifetime can be improved with a simple structure. Furthermore, the area in which the solder grain size is small can be controlled by adjusting the area in which the uneven portion 4231 is formed.

### Second Embodiment

The present embodiment is a modification based on the preceding embodiment, and the description of the preceding embodiment can be incorporated. In the preceding embodiment, the uneven portion 4231 is provided on the surface of the Ni electrode 423 to reduce the solder grain size in the part of the solder 91 adjacent to the semiconductor element 40. Alternatively, the end portion of the protective film 45 may be provided with unevenness.

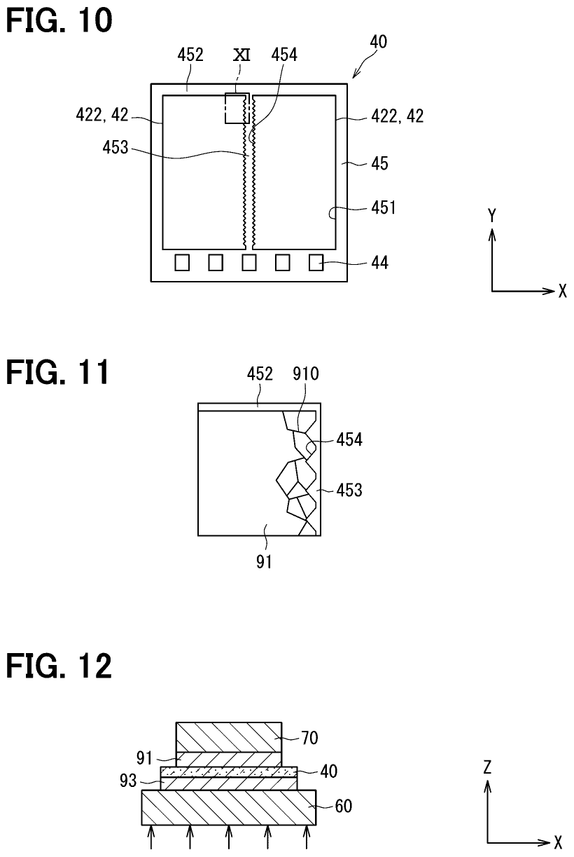

FIG. 10 is a plan view illustrating a semiconductor element 40 of a semiconductor device 20 according to the present embodiment. In FIG. 10, illustrations of the active region 411 including the IGBT region 411i and the diode region 411d and the peripheral region 412 are omitted. The active region 411 including the IGBT region 411i and the diode region 411d, and the peripheral region 412 have the similar configurations to those shown in FIG. 5.

Similar to the preceding embodiment, the protective film 45 has the partition portion 453. The partition portion 453 passes through the center of the semiconductor element 40 and extends in the Y direction. The partition portion 453 is provided so as to divide the Ni electrode 423 into substantially two equal sections in the X direction. In the plan view, the end portion of the partition portion 453 has a continuous uneven shape. The protective film 45 has an uneven portion 454 at the end of the partition portion 453. As an example, the uneven portions 454 are provided on both ends of the partition portion 453. The uneven portion 454 is provided over the entire length of the partition portion 453 in the Y direction.

FIG. 11 is an enlarged view of a region XI in FIG. 10. FIG. 11 shows a solder 91 disposed on the emitter electrode 42. In FIG. 11, only a part of the grain boundary 910 is shown. The solder 91 grows into grains from the unevenness provided on the ends of the partition portion 453 as the starting point, when the solder 91 solidifies. Since the crystal grains grow from the unevenness as described above, the crystal grains are smaller on the semiconductor element 40 side. In particular, in the plan view, the crystal grains near the center of the semiconductor element 40 are smaller.

### <Summary of Second Embodiment>

According to the configurations of the present embodiment, it is possible to achieve the similar effects to those achieved the configurations described in the preceding embodiment. Specifically, the ends of the partition portion 453 has the continuous uneven shape. In this way, since the crystal grains grow from the unevenness of the protective film 45 as the starting point, the grain size becomes smaller on the semiconductor element 40 side. Therefore, similarly to the preceding embodiment, the EM lifetime can be improved.

Further, the uneven portions 454 are provided on the ends of the partition portion 453 that passes through the center of the semiconductor element 40. The solder grain size is smaller as closer to the uneven portions 454 in the plan view, and is larger as farther from the uneven portions 454. In other words, the grain size of the solder 91 becomes smaller near the center of the semiconductor element 40. The solder grain size above the diode region 411d can be smaller, especially near the center where the temperature is higher and EM is promoted.

The arrangement of the partition portion 453 is not limited to the example described above. For example, the partition portion 453 may have a cross shape as the planar shape so as to divide the Ni electrode 423 into substantially four equal sections. The partition portion 453 includes a portion extending in the X direction and a portion extending in the Y direction. In such a configuration, the uneven portions 454 may be provided on both ends of the portion extending in the X direction, or on both ends of the portion extending in the Y direction. Of course, the uneven portions 454 may be provided on both the portion extending in the X direction and the portion extending in the Y direction.

Although an example in which the uneven portion 454 is provided over the entire length of the partition portion 453 has been shown, the uneven portion 454 is not limited to such an example. The uneven portion 454 may be provided at least at a part of the entire length of the partition portion 453. The uneven portion 454 may not be provided on both ends of the partition portion 453, but on at least one of the ends of the partition portion 453. By providing the uneven portion at least at a part of the end of the partition portion 453, the solder grain size can be made smaller.

### Third Embodiment

The present embodiment is a modification based on the preceding embodiment(s), and the description of the preceding embodiment(s) can be incorporated. In the preceding embodiment(s), it has not been mentioned about cooling the solder 91 when the solder 91 is solidified. Alternatively, the solder 91 may be solidified by being cooled in a predetermined direction.

### <Manufacturing Method>

An example of a manufacturing method for the semiconductor device 20 according to the first embodiment will be described.

First, each component of the semiconductor device 20 is prepared. Specifically, the semiconductor element 40, wiring members 50 and 60, the conductive spacer 70, and the external connection terminal 80 are prepared. At this time, the semiconductor element 40 having the uneven portion 4231 on the surface of the Ni electrode 423 is prepared. The wiring member 60 is prepared as, for example, a lead frame including the main terminal 82 and the signal terminal 83.

Next, the semiconductor element 40 is placed on the facing surface 60a of the wiring member 60 with the solder 93 interposed therebetween. The semiconductor element 40 is placed on the solder 93 so that the collector electrode 43 faces the wiring member 60. Next, the conductive spacer 70 is placed on the emitter electrode 42 with the solder 91 interposed therebetween. The solder 92 is placed on the surface of the conductive spacer 70 opposite to the semiconductor element 40. The solder 92 is placed with the amount that is sufficient to absorb height variations in the semiconductor device 20. The solders 91, 92 and 93 are provided, for example, as solder foils. The solder 92 may be applied to the conductive spacer 70 as a pre-solder.

In this stacked state, a first reflow is performed. As a result, a connection body in which the semiconductor element 40, the wiring member 60, and the conductive spacer 70 are stacked and integrally connected is obtained. Next, the pad 44 of the semiconductor element 40 is connected to the signal terminal 83 by the bonding wire 90.

Next, the wiring member 50 is placed on one surface of a base (not shown) with the facing surface 50a facing up. Then, the connection body is placed on the wiring member 50 so that the solder 92 faces the wiring member 50, and a second reflow is performed. In the second reflow, a load is applied in the Z direction on the wiring member 60 side so that the height of the semiconductor device 20 becomes a predetermined height.

Next, the sealing body 30 is formed. Although not shown, in the present embodiment, the sealing body 30 is formed by a transfer molding method. The sealing body 30 is molded so as to completely cover the wiring members 50 and 60, and is then cut after molding. The sealing body 30 is cut together with a part of the wiring members 50 and 60. As a result, the back surfaces 50b and 60b are exposed. The back surface 50b is substantially flush with the first surface 30a, and the back surface 60b is substantially flush with the second surface 30b.

The sealing body 30 may be molded in a state where the back surfaces 50b and 60b are pressed against the wall surfaces defining a cavity of a molding die to be in close contact with the wall surfaces. In this case, when the sealing body 30 is molded, the back surfaces 50b and 60b are exposed from the sealing body 30. Therefore, cutting after the molding is unnecessary.

Next, unnecessary portions of the lead frame, such as the tie bars and the peripheral frame, are removed. In this way, the semiconductor device 20 is produced.

### <Cooling of Solder 91>

FIG. 12 is a cross-sectional view illustrating a cooling process in the first reflow. For convenience, the illustration of the solder 92 is omitted in FIG. 12.

In the present embodiment, as shown in FIG. 12, in the cooling after the heating during the reflow, the connection body is cooled from the wiring member 60 side. As a result, the solder 91 is cooled first from the side adjacent to the semiconductor element 40. The solder 91 solidifies from the side adjacent to the semiconductor element 40. When being solidified, the solder 91 starts to grow into grains from the unevenness, as the starting point, the unevenness originating from the Ni electrode 423. Since the solder 91 is cooled from the side adjacent to the wiring member 60, it is possible to enhance the grain growth starting from the unevenness.

### <Summary of Third Embodiment>

According to the present embodiment, in the cooling performed after the heating during the reflow, the connection body is cooled from the side adjacent to the wiring member 60. In other words, the solder 91 is cooled so that the side adjacent to the semiconductor element 40 is cooled before the side adjacent to the conductive spacer 70. As a result, the solder 91 solidifies from the side adjacent to the semiconductor element 40. This can promote the grain growth from the unevenness originating from the Ni electrode 423. Therefore, the crystal grains are smaller on the semiconductor element 40 side. In other words, the cooling described above can promote the grain size reduction of the solder 91 on the semiconductor element 40 side at least in the region overlapping with the diode region 411d.

The cooling described above may be combined with the configuration described in the second embodiment. Since the solder 91 solidifies from the side adjacent to the semiconductor element 40, it is possible to promote the grain growth starting from the unevenness of the partition portion 453 of the protective film 45.

### Fourth Embodiment

The present embodiment is a modification based on the preceding embodiment(s), and the description of the preceding embodiment(s) can be incorporated. In the preceding embodiment(s), the grain size of the part of the solder 91 adjacent to the semiconductor element 40 is by devising the semiconductor element 40. Alternatively, the solder grain size of the part of the solder 91 adjacent to the semiconductor element 40 may be reduced by devising the solder 91.

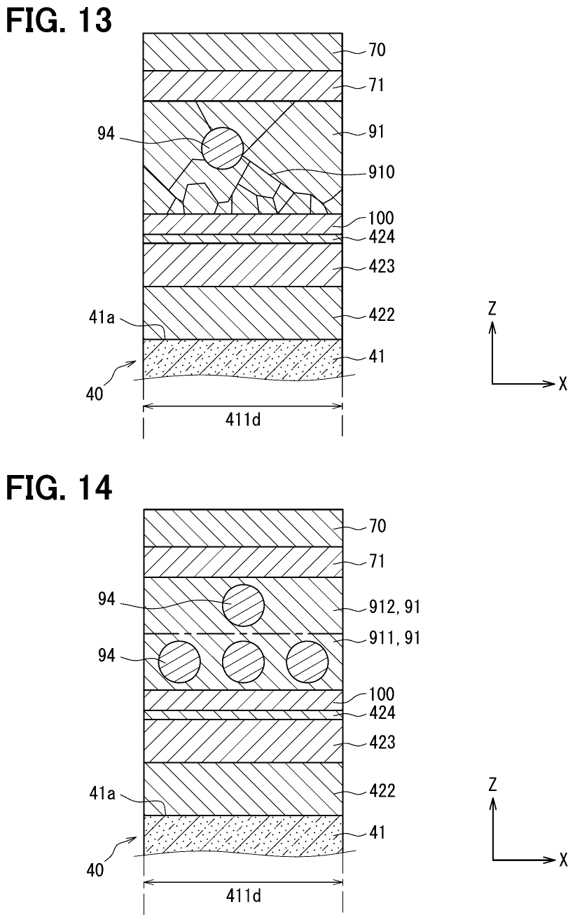

FIG. 13 is a cross-sectional view illustrating the element upper structure of the semiconductor device 20 according to the present embodiment. FIG. 13 is an enlarged cross-sectional view of the emitter electrode 42 and its periphery. FIG. 13 corresponds to FIG. 7.

As shown in FIG. 13, conductive balls 94 are added to the solder 91. The balls 94 are mainly composed of Ni or Cu. Such balls 94 are also referred to as Ni balls or Cu balls. The balls 94 ensure, for example, a minimum thickness of the solder 91. Due to the presence of the balls 94, the solder 91 undergoes grain growth from the balls 94 as the starting points, when solidifying. Since the grain growth of the solder 91 begins from the balls 94 as the starting points, the crystal grains are smaller on the semiconductor element 40 side compared to a configuration in which the balls 94 are not added. In at least the region overlapping with the diode region 411d, the grain size of the solder 91 is smaller on the semiconductor element 40 side than on the conductive spacer 70 side.

### <Summary of Fourth Embodiment>

According to the configuration of the present embodiment, it is possible to achieve the similar effects to those of the configurations described in the preceding embodiment(s). Specifically, by adding the balls 94 to the solder 91, the grain growth occurs from the balls 94 as the starting points, and the crystal grains become smaller on the semiconductor element 40 side. As a result, at least in the region overlapping with the diode region 411d, the grain size of the solder 91 is smaller on the semiconductor element 40 side than on the conductive spacer 70 side. Therefore, the EM lifetime can be improved.

The effects of the balls 94 were also confirmed through a prototype. It was confirmed that the grain size of the part of the solder 91 adjacent to the semiconductor element 40 was reduced by adding the balls 94. It was also confirmed that the disappearance of the alloy layer 100 was slowed down, that is, the progression of the EM were slowed down. At this time, the Ni electrode 423 was formed by an electroless NiP plating. The composition of the alloy layer 100 was (Ni—Cu)₃Sn₄.

### <Modification>

The solder 91 may have a multi-layer structure, and the occupancy rate of the balls 94 per unit volume may differ from layer to layer. In an example shown in FIG. 14, the solder 91 has a first layer 911 and a second layer 912. The first layer 911 is a layer on the semiconductor element 40 side, and the second layer 912 is a layer on the conductive spacer 70 side. The first layer 911 is the layer closest to the semiconductor element 40, and the second layer 912 is another layer other than the first layer 911. FIG. 14 corresponds to FIG. 13. For convenience, the illustration of the grain boundaries 910 is omitted in FIG. 14.

In the example shown in FIG. 14, the occupancy rate of the balls 94 in the first layer 911 is higher than the occupancy rate of the balls 94 in the second layer 912. The amount of the balls 94 is greater in the first layer 911 than in the second layer 912. Therefore, it is possible to further enhance the effect of reducing the grain size of the solder 91 on the semiconductor element 40 side.

In addition, the occupancy rate of the balls 94 in the first layer 911 may be made higher than the occupancy rate of the balls 94 in the second layer 912 by making the diameters of the balls 94 different between the first layer 911 and the second layer 912. Both the amount and the diameter of the balls may be differentiated between the first layer 911 and the second layer 912.

The structure described above can be realized, for example, by arranging two layers of solder foils having different ball occupancy rates. Alternatively, three layers of solder foils without the balls may be stacked together, and the number and/or diameter of the balls 94 disposed between the respective layers of the solder foils being different.

The number of layers of the solder 91 is not limited to two. The number of layers of the solder 91 may be three or more. Also in the case of three or more layers, it is sufficient that the occupancy rate of the balls 94 in the first layer 911 closest to the semiconductor element 40 is higher than the occupancy rate of the balls 94 in the remaining layers.

### Fifth Embodiment

The present embodiment is a modification based on the preceding embodiment(s), and the description of the preceding embodiment(s) can be incorporated. In the preceding embodiment(s), it has not been mentioned about cooling the solder 91 to which the balls 94 have been added when the solder 91 is solidified. Alternatively, the solder 91 may be solidified by being cooled in a predetermined direction.

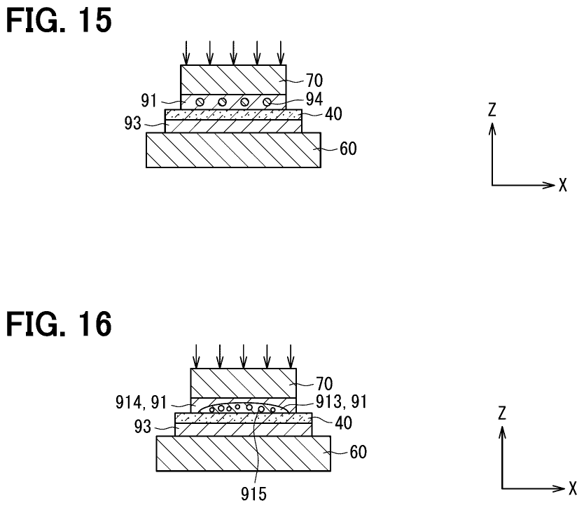

FIG. 15 is a cross-sectional view illustrating a cooling process during reflow. FIG. 15 corresponds to FIG. 12.

In the present embodiment, as shown in FIG. 15, in the cooling process after heating during the reflow, the connection body is cooled from the conductive spacer 70 side. The thermal resistance of the heat transfer path of the solder 91 is smaller on the conductive spacer 70 side than on the wiring member 60 side. The balls 94 cool quickly due to cooling from the conductive spacer 70 side. Since the solder 91 starts to aggregate from the balls 94 as the starting points, the grain growth from the balls 94 can be promoted by cooling from the conductive spacer 70 side.

### <Summary of Fifth Embodiment>

According to the present embodiment, in the cooling process after heating in during the reflow, the connection body is cooled from the conductive spacer 70 side. This allows the balls 94 to cool quickly. As a result, the grain growth of the solder 91 starting from the balls 94 can be promoted. Therefore, it is possible to promote the grain size reduction of the solder 91 on the semiconductor element 40 side at least in the region overlapping with the diode region 411d.

### <Modification>

Also in configurations in which the above-mentioned improvements are not implemented on the semiconductor element 40 or the solder 91, the connection body may be cooled from the conductive spacer 70 side. In this case, the solder 91 solidifies from the conductive spacer 70 side. During the cooling process, a liquid portion 913 remains on the semiconductor element 40 side, as shown in FIG. 16. The solder 91 includes the liquid portion 913 and a solidified portion 914. The liquid portion 913 is a portion of the solder 91 that has not yet solidified, that is, a portion that is in a molten state. FIG. 16 corresponds to FIG. 15.

Voids 915 such as micro voids and impurities gather in the liquid portion 913 as the solder 91 solidifies. Therefore, when the liquid portion 913 solidifies, grain growth occurs from the voids 915 and the like as starting points. This allows the grain size of the solder 91 to be smaller on the semiconductor element 40 side than on the conductive spacer 70 side, at least in the region overlapping with the diode region 411d.

### Other Embodiments

The disclosure in this specification, drawings, and the like is not limited to the embodiments illustrated. The disclosure encompasses the embodiments illustrated and modifications by those skilled in the art based thereon. For example, the disclosure is not limited to the combinations of components and/or elements shown in the embodiments. The disclosure may be implemented in various combinations. The disclosure may have additional parts that may be added to the embodiments. The disclosure encompasses omission of components and/or elements of the embodiments. The disclosure encompasses replacements of components and/or elements between one embodiment and another embodiment, or combinations thereof. The disclosed technical scopes are not limited to the description of the embodiments. It should be understood that some disclosed technical ranges are indicated by description of claims, and includes every modification within the equivalent meaning and the scope of description of claims.

The disclosure in this specification, the drawings and the like is not limited by the description of the claims. The disclosure in the specification, the drawings, and the like encompasses the technical ideas described in the claims, and further extends to a wider variety of technical ideas than those in the claims. Therefore, various technical ideas can be extracted from the disclosure of the specification, the drawings and the like without being limited to the description of the claims.

When an element or a layer is described as “disposed above”, “coupled to” “connected to” or “combined with”, the element or the layer may be directly disposed above, coupled to, connected to, or combined with another element or another layer, or an intervening element or an intervening layer may be present therebetween. In contrast, when an element is described as “directly disposed on”, “directly coupled to”, “directly connected to”, or “directly combined with” another element or another layer, there are no intervening elements or layers present. Other terms used to describe the relationships between elements (for example, “between” vs. “directly between”, and “adjacent” vs. “directly adjacent”) should be interpreted similarly. As used herein, the term “and/or” includes any combination and all combinations relating to one or more of the related listed items. For example, the term A and/or B includes only A, only B, or both A and B.

Spatial relative terms “inside”, “outside”, “rear”, “bottom”, “low”, “top”, “high”, and the like are used herein to facilitate the description that describes relationships between one element or feature and another element or feature. Spatial relative terms can be intended to include different orientations of a device in use or operation, in addition to the orientations illustrated in the drawings. For example, when a device in a drawing is turned over, elements described as “below” or “directly below” other elements or features are oriented “above” the other elements or features. Therefore, the term “below” can include both above and below. The device may be oriented in the other direction (rotated 90 degrees or in any other direction) and the spatially relative terms used herein are interpreted accordingly.

The vehicle drive system 1 is not limited to the configuration described above. The vehicle drive system 1 having one motor generator 3 has been illustrated. However, the configuration of the vehicle drive system 1 is not limited to the example illustrated. The vehicle drive system 1 may have multiple motor generators. Although the power conversion device 4 having the inverter 6 has been illustrated as the electric power converter, the configuration of the power conversion device 4 is not limited to the example illustrated. For example, the power conversion device 4 may have multiple inverters. As another example, the power conversion device 4 may have at least one inverter and a converter. The power conversion device 4 may only have the converter.

The configuration of the semiconductor device 20 is not limited to the example described above. The semiconductor device 20 may include at least a semiconductor element, an upper conductor, solder that joins an upper electrode of the semiconductor element to the upper conductor, and an alloy layer interposed between the upper electrode and the solder.

Instead of the conductive spacer 70, the wiring member 50 may be provided with a protrusion. In this case, the wiring member 60 corresponds to the upper conductor.

The semiconductor device 20 having the double-sided heat dissipation structure has been illustrated as an example, but the present disclosure is not limited thereto. The present disclosure can also be applied to a one-sided heat dissipation structure. For example, the collector electrode 43 is connected to a heat sink or a metal body of a substrate, and the emitter electrode 42 is connected to a lead. In this case, the lead corresponds to the upper conductor.

Although an example has been illustrated in which the semiconductor device 20 includes only one semiconductor element 40 that constitutes one arm, the present disclosure is not limited to this example. The semiconductor device 20 may include multiple semiconductor elements 40 that constitutes one arm. In other words, multiple semiconductor elements 40 may be connected in parallel to each other to constitute one arm. Further, the semiconductor device 20 may include multiple semiconductor elements 40 that constitute the upper-lower arm circuit 9 for one phase. Alternatively, the semiconductor device 20 may include multiple semiconductor elements 40 that constitute the upper-lower arm circuits 9 for multiple phases.

The arrangement of the IGBT region 411i and the diode region 411d is not particularly limited. Instead of the alternating arrangement in the X direction, the alternating arrangement in the Y direction may be employed. Instead of the stripe-like arrangement, an interspersed arrangement in which the diode regions 411d may be interspersed as islands.

Although an example in which the back surfaces 50b and 60b of the wiring members 50 and 60 are exposed from the sealing body 30 has been illustrated, the present disclosure is not limited to this example. At least one of the back surfaces 50b and 60b may be covered with the sealing body 30. At least one of the back surfaces 50b and 60b may be covered with an insulating member (not shown) separate from the sealing body 30. The semiconductor device 20 may not include the sealing body 30.

Although an example in which the area of the diode region 411d is smaller than the area of the IGBT region 411i has been illustrated, the present disclosure is not limited to this example. The present disclosure can also be applied to a configuration in which the area of the diode region 411d and the area of the IGBT region 411i are substantially equal to each other, or a configuration in which the area of the IGBT region 411i is smaller than the area of the diode region 411d. When the area of the IGBT region 411i is small, the EM lifetime is unlikely to be a problem. The direction of the main current is opposite to the direction of the return current. When the main current flows, electrons move from the conductive spacer 70 side toward the semiconductor element 40 side. Because the area of the conductive spacer 70 is large, the EM lifetime is unlikely to be a problem.

What is claimed is:

1. A semiconductor device comprising:
a semiconductor element including a semiconductor substrate and an upper electrode disposed on a first surface of the semiconductor substrate, the semiconductor substrate having an insulated gate bipolar transistor (IGBT) region and a diode region;
an upper conductor disposed to face the upper electrode;
an upper solder interposed between the upper electrode and the upper conductor and joining the upper electrode and the upper conductor; and
an alloy layer interposed between the upper electrode and the upper solder, wherein
the upper electrode includes an aluminum (Al) electrode disposed on the first surface and a nickel (Ni) electrode disposed on the Al electrode,
the upper solder contains copper (Cu) and tin (Sn),
the alloy layer contains Ni, Cu, and Sn, and
at least in a region overlapping with the diode region in a plan view along a thickness direction of the semiconductor substrate, the upper solder has a grain size that is smaller on a side adjacent to the semiconductor element than on a side adjacent to the upper conductor.

2. The semiconductor device according to claim 1, wherein
the semiconductor element includes a lower electrode disposed on a second surface of the semiconductor substrate, the second surface being opposite to the first surface;
the semiconductor device further comprising:
a lower conductor disposed to face the lower electrode; and
a lower solder interposed between the lower electrode and the lower conductor and joining the lower electrode and the lower conductor, wherein
the grain size of the upper solder on the side adjacent to the semiconductor element at least in the region overlapping with the diode region is smaller than a grain size of the lower solder.

3. The semiconductor device according to claim 1, wherein
the Ni electrode has an uneven portion having continuous unevenness on a surface at least in the region overlapping with the diode region.

4. The semiconductor device according to claim 1, wherein
the semiconductor element includes a protective film disposed on the first surface of the semiconductor substrate,
the protective film has an opening portion defining an opening that exposes the Ni electrode so as to provide a joining portion, and a partition portion that divides the Ni electrode into a plurality of sections, and
an end portion of the partition portion has a continuous uneven shape in the plan view.

5. The semiconductor device according to claim 1, wherein
the upper solder contains a conductive ball therein.

6. The semiconductor device according to claim 5, wherein
the upper solder has a multi-layer structure including a plurality of layers, the plurality of layers including a first layer at a position closest to the semiconductor element, and
an occupancy rate of the conductive ball per unit volume in the upper solder is higher in the first layer than in another layer other than the first layer.

7. The semiconductor device according to claim 5, wherein
the conductive ball contains Ni or Cu.

8. The semiconductor device according to claim 1, wherein
the Ni electrode is a Ni plating film containing phosphorous (P).
